(19) United States
(12) Patent Application Publication
(10) Pub. No.: US 2007/0178627 A1
(43) Pub. Date: Aug. 2, 2007

(54) Flip-chip semiconductor device and method for fabricating the same

(75) Inventors: Yih Jenn Jiang, Taichung (TW); Han Ping Pu, Taipei Hsien (TW); Cheng Hsu Hsiao, Taichung Hsien (TW)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (TW)

(21) Appl. No.: 11/648,048

(22) Filed: Dec. 28, 2006

(30) Foreign Application Priority Data
Jan. 27, 2006 (TW) 095103437

(51) Int. Cl. H01L 21/00

(52) U.S. Cl. 438/108

(57) ABSTRACT

A flip-chip semiconductor device and a method for fabricating the same are provided. A first underfill material with a low Young's modulus is applied to corners of a chip mounting area defined on a substrate. A chip is mounted on and electrically connected to the chip mounting area by a plurality of conductive bumps, allowing the first underfill material to encapsulate corners of the chip. A second underfill material with a high Young's modulus is used to fill a gap between the chip and the substrate to protect the conductive bumps and support the chip.

### FIELD OF THE INVENTION

The present invention relates to flip-chip semiconductor devices and fabrication methods thereof, and more particularly, to a flip-chip semiconductor device for preventing delamination at a chip incorporated therein, and a method for fabricating the flip-chip semiconductor device.

### BACKGROUND OF THE INVENTION

Flip-chip semiconductor package, as implied in the name, refers to a package structure using a flip-chip technique to electrically connect an active surface of a chip to a surface of a substrate via a plurality of conductive bumps. A plurality of solder balls are implanted on another surface of the substrate and serve as input/output (I/O) connections for allowing the chip to be electrically connected to an external device. By the above arrangement, the size of the semiconductor package can be significantly reduced such that the chip may be made dimensionally closer to the substrate, and the semiconductor package does not require bonding wires, thereby reducing impedance and improving electrical performance of the semiconductor package. These advantages make the flip-chip packaging technology become the mainstream packaging technology.

FIGS. 1A and 1B are a plan view and a cross-sectional view of a conventional flip-chip semiconductor package, respectively. During fabrication of the flip-chip semiconductor package, an underfilling step is usually performed by using an underfill material 12 (such as a thermosetting resin) to fill a gap between a chip 10 and a substrate 11 and encapsulate conductive bumps 13 that electrically connect the chip 10 to the substrate 11. The conductive bumps 13 are strengthened and held in position by the underfill material 12, and thus can well support the chip 10 mounted thereon. Related prior arts include U.S. Pat. No. 6,255,704 and U.S. Pat. No. 6,074,895.

However, due to the surface tension of the underfill material 12, the underfill material 12 filling the gap provides the smallest adhesion protection at corners of the chip 10. Further, due to large mismatch in coefficient of thermal expansion (CTE) between the chip 10 and the substrate 11, thermal stress and thermal deformation generated during a thermal cycle of chip packaging are directly proportional to a distance from a location where no deformation occurs, as represented by an equation: δ (deformation amount)=α (material CTE)×L (distance from the location without material deformation)×Δt (temperature variation). Since the corners of the chip 10 are located farthest from a center of the chip 10 where no deformation occurs, the corners suffer the greatest thermal stress and thermal deformation. However as described above, the corners of the chip 10 are not sufficiently protected by the underfill material 12, such that the underfill material 12 located at a peripheral portion of the gap becomes delaminated from the corners of the chip 10, as indicated by the sign S in FIG. 1B. If the situation is worse, the delamination spreads and thereby adversely affects the electrical performance of the conductive bumps.

To solve the above problem of thermal stress caused by CTE mismatch, generally an underfill material having a low Young's modulus is employed to absorb the thermal stress. Unfortunately, the underfill material having a low Young's modulus cannot sufficiently strengthen the conductive bumps for supporting the chip; instead, an underfill material having a high Young's modulus should be used. However, the underfill material having a higher Young's modulus tends to become delaminated from the chip when experiencing the thermal stress. As a result, for mounting chips of different sizes and types to a substrate, it needs to take much time, effort and trial to find a suitable underfill material, thereby increasing the fabrication time and cost undesirably.

Therefore, the problem to be solved here is to provide a flip-chip semiconductor device and a method for fabricating the same, which can effectively avoid delamination at corners of a chip and also provide sufficient protection for conductive bumps in order to overcome the drawbacks in the prior art.

### SUMMARY OF THE INVENTION

In view of the foregoing drawbacks in the prior art, an objective of the present invention is to provide a flip-chip semiconductor device and a method for fabricating the same, which can prevent delamination from occurrence at a chip in the semiconductor device.

Another objective of the present invention is to provide a flip-chip semiconductor device and a method for fabricating the same, which can effectively protect and support conductive bumps connected to a chip in the semiconductor device.

A further objective of the present invention is to provide a flip-chip semiconductor device and a method for fabricating the same, which can increase an amount of an underfill material applied to corners of a chip in the semiconductor device.

To achieve the above and other objectives, the present invention proposes a method for fabricating a flip-chip semiconductor device, the method comprising the steps of: providing a substrate defined with at least one chip mounting area thereon and applying a first underfill material to corners of the chip mounting area; mounting and electrically connecting a chip to the chip mounting area via a plurality of conductive bumps, wherein the first underfill material is disposed between corners of the chip and the substrate; and filling a second underfill material into a gap between the chip and the substrate. The first underfill material has a smaller Young's modulus than that of the second underfill material.

The present invention also proposes a flip-chip semiconductor device, comprising: a substrate defined with at least one chip mounting area thereon; at least one chip mounted on and electrically connected to the chip mounting area by a plurality of conductive bumps; a first underfill material applied to corners of the chip mounting area and disposed between corners of the chip and the substrate; and a second underfill material filling a gap between the chip and the substrate. The first underfill material has a smaller Young's modulus than that of the second underfill material.

Therefore, in the flip-chip semiconductor device and the method for fabricating the same according to the invention, firstly, a first underfill material with a low Young's modulus is applied to corners of a chip mounting area defined on a substrate. Next, at least one chip is mounted on and electrically connected to the chip mounting area of the substrate by a plurality of conductive bumps, wherein the first underfill material is disposed between corners of the chip and the substrate. Then, a second underfill material with a high Young's modulus is used to fill a gap between the chip and the substrate so as to protect the conductive bumps and support the chip. By such arrangement, the first underfill material with a low Young's modulus, which is applied to the corners of the chip, can protect the corners of the chip and absorb thermal stress to prevent delamination from occurrence at the corners of the chip; and the second underfill material with a high Young's modulus, which is applied under the chip and encapsulates the conductive bumps, can effectively protect the conductive bumps and support the chip.

Moreover, as different underfill materials with high and low Young's modului are used to fill a space under the chip and encapsulate the corners of the chip in the present invention, sufficient protection can be provided for the corners of the chip against delamination, and effective support and protection can be provided for the conductive bumps under the chip, such that the problems of taking much time and cost on finding a single suitable underfill material and not able to protect both the chip corners and the conductive bumps as encountered in the prior art can be solved by the present invention.

### BRIEF DESCRIPTION OF THE DRAWINGS

The present invention can be more fully understood by reading the following detailed description of the preferred embodiments, with reference made to the accompanying drawings, wherein:

FIG. 1A (PRIOR ART) is a plan view of a conventional flip-chip semiconductor package;

FIG. 1B (PRIOR ART) is a cross-sectional view of the conventional flip-chip semiconductor package; and

FIGS. 2A to 2E are schematic diagrams of a flip-chip semiconductor device and a method for fabricating the same according to the present invention.

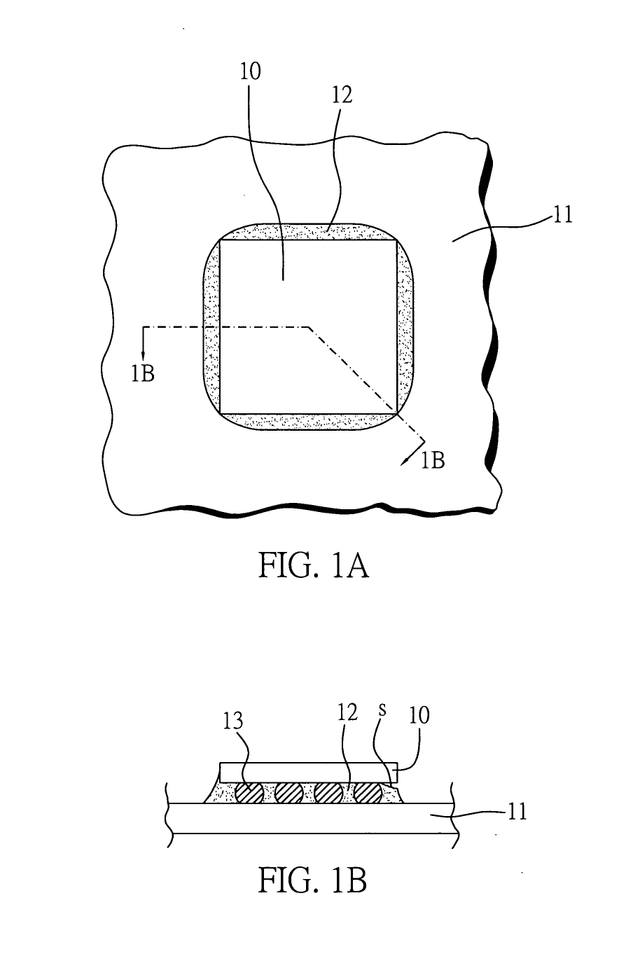

### DETAILED DESCRIPTION OF THE PREFERRED EMBODIMENTS

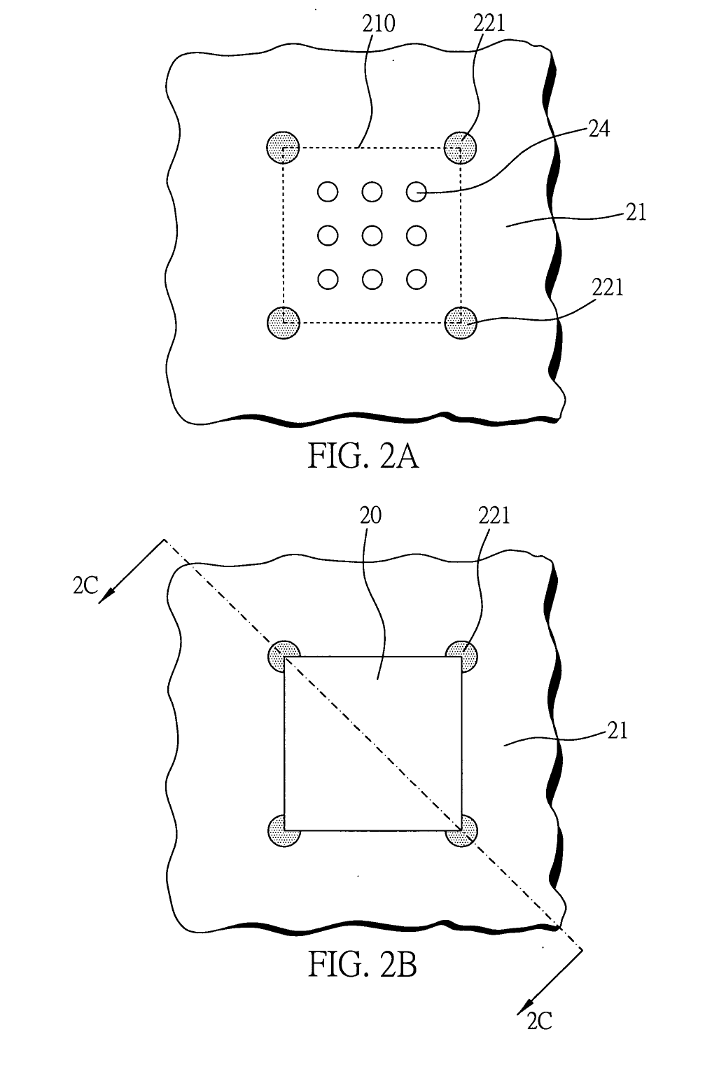

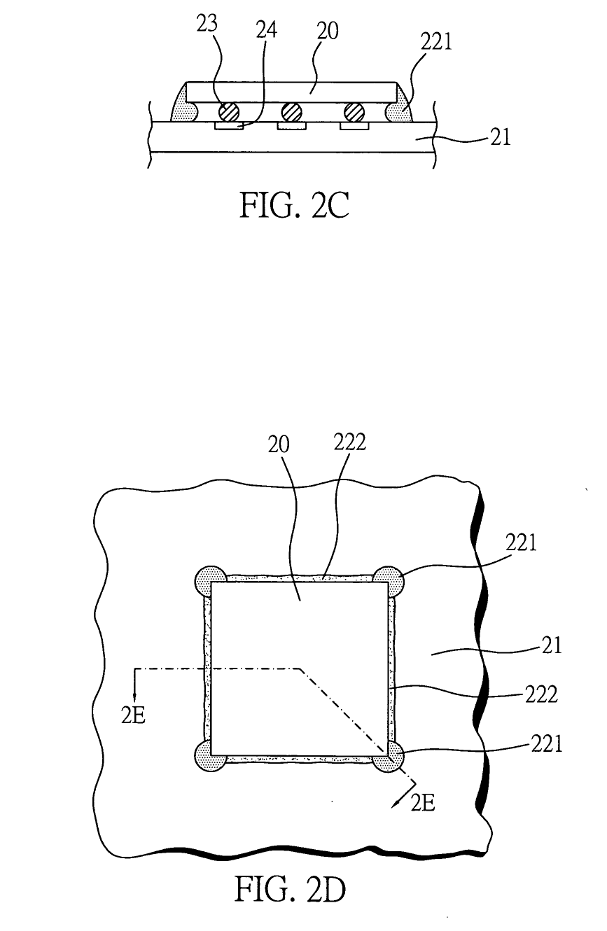

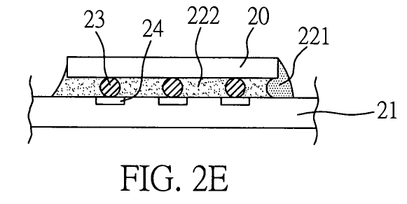

Preferred embodiment of a flip-chip semiconductor device and a method for fabricating the same as proposed in the present invention are described as follows with reference to FIGS. 2A to 2E. It should be understood that the drawings are simplified schematic diagrams only showing the elements relevant to the present invention, and the layout of elements could be more complicated in practical implementation.

FIGS. 2A to 2E are schematic diagrams of the flip-chip semiconductor device and the method for fabricating the same according to the present invention.

As shown in FIG. 2A, a substrate 21 is provided on which at least one chip mounting area 210 (as indicated by the dotted line) is defined for accommodating at least one chip. A plurality of bond pads 24 are formed within the chip mounting area 210, for mounting and electrically connecting the at least one chip in a subsequent process. A first underfill material 221 is applied to corners of the chip mounting area 210 of the substrate 21. The first underfill material 221 is a material with a low Young's modulus and has a glass transition temperature (Tg) lower than 80° C.

As shown in FIG. 2B, a flip-chip mounting process is performed in which a chip 20 is mounted on the chip mounting area 210 by a plurality of conductive bumps. The conductive bumps are bonded to the bond pads 24 and are reflowed so as to electrically connect the chip 20 to the bond pads 24, and the first underfill material 221 is disposed between corners of the chip 20 and the substrate 21.

FIG. 2C, which is a cross-sectional view of FIG. 2B taken along line 2C-2C, further shows the flip-chip mounting process in which the chip 20 is mounted on and electrically connected to the bond pads 24 of the substrate 21 by the plurality of conductive bumps 23. During the flip-chip mounting process, the first underfill material 221, which has been applied to the corners of the chip mounting area 210 of the substrate 21, is disposed between the corners of the chip 20 and the substrate 21 such that an amount of the underfill material applied to the corners of the chip 20 is increased. Since the first underfill material 221 has a low Young's modulus, it can absorb thermal stress generated due to CTE mismatch between the chip 20 and the substrate 21 and exerted to the corners of the chip 20, thereby preventing delamination from occurrence at the corners of the chip 20.

As shown in FIG. 2D, a second underfill material 222 is used to fill a gap between the chip 20 and the substrate 21. The second underfill material 222 has a larger Young's modulus than that of the first underfill material 221. The second underfill material 222 is a material with a high Young's modulus and has a glass transition temperature (Tg) higher than 80° C.

FIG. 2E, which is a cross-sectional view of FIG. 2D taken along line 2E-2E, further shows that the second underfill material 222 is applied under the chip 20 and encapsulates the conductive bumps 23. Since the second underfill material 222 has a high Young's modulus, it can effectively protect the conductive bumps 23 and support the chip 20.

By the foregoing fabrication method, the present invention also provides a flip-chip semiconductor device, comprising: a substrate 21 defined with at least one chip mounting area thereon; at least one chip 20 mounted on and electrically connected to the chip mounting area 210 of the substrate 21 by a plurality of conductive bumps 23; a first underfill material 221 applied to corners of the chip mounting area 210 and disposed between corners of the chip 20 and the substrate 21; and a second underfill material 222 filling a gap between the chip 20 and the substrate 21. The first underfill material 221 has a smaller Young's modulus than that of the second underfill material 222.

Therefore, in the flip-chip semiconductor device and the method for fabricating the same according to the invention, firstly, a first underfill material with a low Young's modulus is applied to corners of a chip mounting area defined on a substrate. Next, at least one chip is mounted on and electrically connected to the chip mounting area of the substrate by a plurality of conductive bumps, wherein the first underfill material is disposed between corners of the chip and the substrate. Then, a second underfill material with a high Young's modulus is used to fill a gap between the chip and the substrate so as to protect the conductive bumps and support the chip. By such arrangement, the first underfill material with a low Young's modulus, which is applied to the corners of the chip, can protect the corners of the chip and absorb thermal stress to prevent delamination from occurrence at the corners of the chip; and the second underfill material with a high Young's modulus, which is applied under the chip and encapsulates the conductive bumps, can effectively protect the conductive bumps and support the chip.

Moreover, as different underfill materials with high and low Young's modului are used to fill a space under the chip and encapsulate the corners of the chip in the present invention, sufficient protection can be provided for the corners of the chip against delamination, and effective support and protection can be provided for the conductive bumps under the chip, such that the problems of taking much time and cost on finding a single suitable underfill material and not able to protect both the chip corners and the conductive bumps as encountered in the prior art can be solved by the present invention.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method for fabricating a flip-chip semiconductor device, the method comprising the steps of:
providing a substrate defined with at least one chip mounting area thereon and applying a first underfill material to corners of the chip mounting area;
mounting and electrically connecting at least one chip to the chip mounting area of the substrate via a plurality of conductive bumps, wherein the first underfill material is disposed between corners of the chip and the substrate; and
filling a second underfill material into a gap between the chip and the substrate.

2. The method of claim 1, wherein the first underfill material has a smaller Young's modulus than that of the second underfill material.

3. The method of claim 1, wherein a plurality of bond pads are formed within the chip mounting area of the substrate, and the plurality of conductive bumps are bonded to the bond pads and are reflowed so as to electrically connect the chip to the bond pads.

4. The method of claim 1, wherein the first underfill material is a material with a low Young's modulus.

5. The method of claim 1, wherein the first underfill material has a glass transition temperature (Tg) lower than 80° C.

6. The method of claim 1, wherein the second underfill material is a material with a high Young's modulus.

7. The method of claim 1, wherein the second underfill material has a glass transition temperature (Tg) higher than 80° C.

8. The method of claim 1, wherein the second underfill material encapsulates the conductive bumps.

9. A flip-chip semiconductor device comprising:
a substrate defined with at least one chip mounting area thereon;
at least one chips mounted on and electrically connected to the chip mounting area of the substrate by a plurality of conductive bumps;
a first underfill material applied to corners of the chip mounting area and disposed between corners of the chip and the substrate; and
a second underfill material filling a gap between the chip and the substrate.

10. The flip-chip semiconductor device of claim 9, wherein the first underfill material has a smaller Young's modulus than that of the second underfill material.

11. The flip-chip semiconductor device of claim 9, wherein the substrate further comprises a plurality of bond pads formed within the chip mounting area, such that the plurality of conductive bumps are bonded to the bond pads and are reflowed so as to electrically connect the chip to the bond pads.

12. The flip-chip semiconductor device of claim 9, wherein the first underfill material is a material with a low Young's modulus.

13. The flip-chip semiconductor device of claim 9, wherein the first underfill material has a glass transition temperature (Tg) lower than 80° C.

14. The flip-chip semiconductor device of claim 9, wherein the second underfill material is a material with a high Young's modulus.

15. The flip-chip semiconductor device of claim 9, wherein the second underfill material has a glass transition temperature (Tg) higher than 80° C.

16. The flip-chip semiconductor device of claim 9, wherein the conductive bumps are encapsulated by the second underfill material.
